(19) United States
(12) Patent Application Publication
(10) Pub. No.: US 2026/0229796 A1
(43) Pub. Date: Aug. 6, 2026

(54) PRESSING MEMBER AND POWER SUPPLY DEVICE

(71) Applicant: TDK Corporation, Tokyo (JP)

(72) Inventors: Akira HIRAOKA, Tokyo (JP); Tomohiko UCHIYAMA, Tokyo (JP); Daiki HIRAOKA, Tokyo (JP)

(73) Assignee: TDK Corporation, Tokyo (JP)

(21) Appl. No.: 19/463,322

(22) Filed: Jan. 29, 2026

(30) Foreign Application Priority Data
Feb. 5, 2025 (JP) 2025-017462

(51) Int. Cl. H01R 4/48; B60L 53/16; H02J 7/70

(52) U.S. Cl. CPC H01R 4/489; B60L 53/16; H02J 7/751

(57) ABSTRACT

A pressing member that can be applied to a plurality of substrates having same shape. A pressing member is formed as a plate extending along longitudinal direction from one end portion to other end portion opposite to the one end portion, the pressing member includes: first fixing portion on one end portion and fixable to a substrate or housing accommodating the substrate; second fixing portion on an intermediate portion between the one end portion and the other end portion and fixable to the substrate or housing; pair of first spring portions that are on the one end portion, arranged in a width direction intersecting the longitudinal direction, extend from first fixing portion toward second fixing portion, are elastically deformable; and a pair of second spring portions that are on the intermediate portion, arranged in the width direction, extend from second fixing portion toward first fixing portion, and are elastically deformable.

### CROSS REFERENCE TO RELATED APPLICATIONS

This application claims the benefit of Japanese Priority Patent Application No. 2025-017462 filed on Feb. 5, 2025, the entire contents of which are incorporated herein by reference.

### FIELD

The present disclosure relates to a pressing member and a power supply device including the pressing member.

### BACKGROUND

A power supply device incorporated in a battery charger or the like for an on-vehicle battery operates under a severe environment in which the power supply device is constantly exposed to vibrations and high temperatures. Such a power supply device is provided with a pressing member such as a leaf spring for pressing an electronic component such as a semiconductor element against a substrate in order to improve the connection reliability. For example, a pressing member disclosed in Patent Publication JP-A-2016-63200 includes a support portion and a plurality of pressing portions that are arranged so as to face each other with the support portion being located therebetween. The plurality of pressing portions is arranged so as to be separated from each other on the long sides of the support portion having a substantially rectangular shape, and elastically press a plurality of components toward a housing.

### SUMMARY

In the pressing member disclosed in Patent Publication JP-A-2016-63200, the plurality of pressing portions is arranged at positions corresponding to positions of the plurality of components mounted on the substrate. Such a pressing member is a special product for each substrate, and if the arrangement of the components is changed, a new pressing member must be designed in accordance with the components.

The present disclosure has been made in view of such circumstances, and an object thereof is to provide a technique relating to a pressing member that can be applied to a plurality of types of substrates having the same shape.

A pressing member according to one aspect of the present disclosure is formed as a plate extending along a longitudinal direction from one end portion to the other end portion opposite to the one end portion, and includes: a first fixing portion provided on the one end portion and fixable to a substrate or a housing accommodating the substrate; a second fixing portion provided on an intermediate portion between the one end portion and the other end portion and fixable to the substrate or the housing; a pair of first spring portions that are provided on the one end portion, arranged in a width direction intersecting the longitudinal direction, extend from the first fixing portion toward the second fixing portion, and are elastically deformable; and a pair of second spring portions that are provided on the intermediate portion, arranged in the width direction, extend from the second fixing portion toward the first fixing portion, and are elastically deformable.

According to this aspect, because the pressing member has the pair of first spring portions and the pair of second spring portions that are arranged in the width direction, for example, the pressing member can press a single electronic component with the two first spring portions, or, for example, press an electronic component of one of the first spring portions and press another electronic component with the other first spring portion. The same applies to the second spring portions. Therefore, even if the design of the substrate is changed, the pressing member having the same shape can be used. Because the first spring portions and the second spring portions are arranged so as to oppose each other in the longitudinal direction, and the pair of first spring portions are arranged in the width direction in a section adjacent to the first fixing portion, the distance between the first fixing portion and the first spring portions is shorter as compared with the aspect described in Patent Publication JP-A-2016-63200 in which many spring portions are arranged in the longitudinal direction, and therefore the stress and reaction force can be adjusted easily. Accordingly, electronic components can be pressed with an optimum pressing force. The same applies to the second spring portions.

In the above aspect, the pressing member may further include a pair of third spring portions that are provided between the first fixing portion and the second fixing portion, are arranged in the lengthwise direction, extend in the width direction, and are elastically deformable.

According to this aspect, because the pressing member includes the pair of third spring portions extending in a direction different from that of the first and second spring portions, the number of electronic components to be pressed can be increased. Since the pressing member includes the pair of third spring portions arranged in the longitudinal direction, for example, both of the third spring portions can press a single electronic component, or, for example, one of the third spring portions can press an electronic component and the other third spring portion can press another electronic component. Because the pair of third spring portions are sandwiched between the first and second fixing portions, the distance between the first and second fixing portions and the third spring portions is shorter as compared with the aspect described in Patent Publication JP-A-2016-63200 in which many spring portions are arranged in the longitudinal direction, and therefore the stress and reaction force can be adjusted easily. Accordingly, electronic components can be pressed with an optimum pressing force.

In the above aspect, the pair of first spring portions and the pair of second spring portions may have different lengths in the longitudinal direction.

In the above aspect, the length of the pair of first spring portions in the longitudinal direction may be different from the length of the pair of third spring portions in the width direction.

The greater the thickness of an electronic component, the shorter the distance from the fixing portion to an upper surface of the electronic component. Also, the distance from the fixing portion fixed to the housing (e.g., the first fixing portion) to the electronic component may be long, and the distance from the fixing portion fixed to the substrate (e.g., the second fixing portion) to the electronic component may be short. According to these aspects, it is possible to press an electronic component with an optimum pressing force by changing the length of the spring portions.

In the above aspect, the first and second fixing portions may be fixed to the substrate or the housing by means of fastening screws.

According to this aspect, the pressing member can be securely fixed using the fastening screws.

A power supply device according to one aspect of the present disclosure includes the pressing member according to any one of the above aspects and a substrate, wherein the substrate includes: a first voltage output circuit for outputting a first voltage; and a second voltage output circuit for outputting a second voltage, and an electronic component may be a semiconductor element that constitutes the first and second voltage output circuits.

According to this aspect, the same pressing member can be used even when the design of the substrate is changed. Thus, even when the first and second voltage output circuits have the arrangement of substantially the same electronic components or different electronic components, the electronic components constituting the plurality of circuits can be pressed. For example, both the first and second voltage output circuits may be of the center-tap type or full-bridge type and have the arrangement of substantially the same electronic components. For example, the first and second voltage output circuits may have the arrangement of different electronic components in which one of the first and second voltage output circuits may be of the center-tap type and the other may be of the full-bridge type.

An object of the present disclosure is to provide a technique relating to a pressing member that can be applied to a plurality of types of substrates having the same shape.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a plan view showing an example of a power supply device including a pressing member according to one aspect of the present disclosure;

FIG. 2 is a perspective view showing an example of a pressing member according to one aspect of the present disclosure;

FIG. 3 is a side view of the pressing member shown in FIG. 2;

FIG. 4 is a plan view of the pressing member shown in FIG. 2;

FIG. 5 is a plan view schematically showing a pair of first spring portions shown in FIG. 4;

FIG. 6 is a plan view showing an example of a substrate shown in FIG. 1;

FIG. 7A is a circuit diagram for explaining a full-bridge type first voltage output circuit shown in FIG. 6;

FIG. 7B is a circuit diagram for explaining a center-tap type second voltage output circuit shown in FIG. 6; and

FIG. 8 is a perspective view showing an exploded view of a power supply device in which the pressing member shown in FIG. 2 is attached to the substrate shown in FIG. 6.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

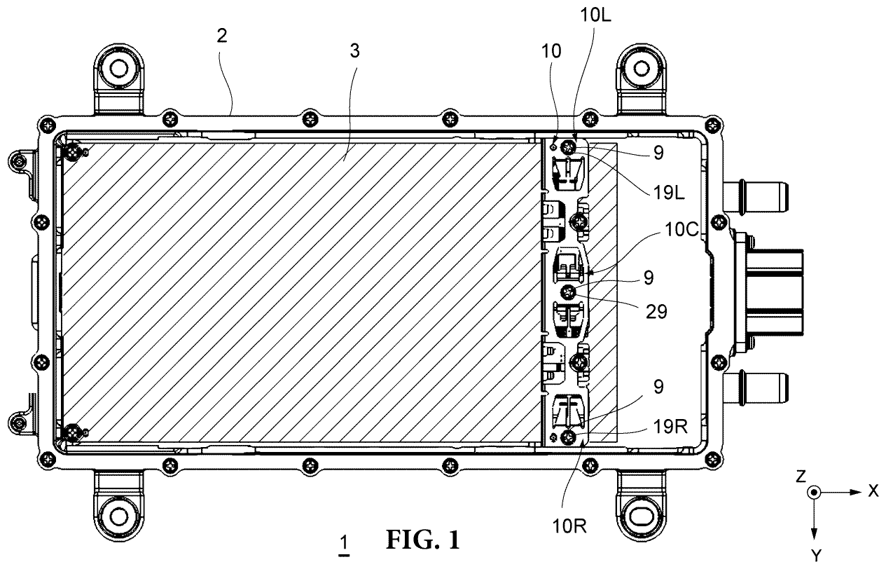

Preferred example embodiment of the present disclosure will be described with reference to the accompanying drawings. Note that elements designated by same reference signs in the respective drawings share an identical or similar configuration. Hereinafter, each configuration will be described in detail with reference to FIGS. 1 to 8.

FIG. 1 is a plan view showing an example of a power supply device 1 having a pressing member 10 according to one aspect of the present disclosure. As in the illustrated example, the pressing member 10 according to the present disclosure is suitable for the power supply device 1. In addition to the pressing member 10, the power supply device 1 includes a substrate 3 having a voltage output circuit and the like (shown by the hatching in FIG. 1), a housing 2 for accommodating the substrate 3, and the like. However, the application of the pressing member 10 is not limited to the power supply device 1, and the pressing member 10 can be applied to various devices.

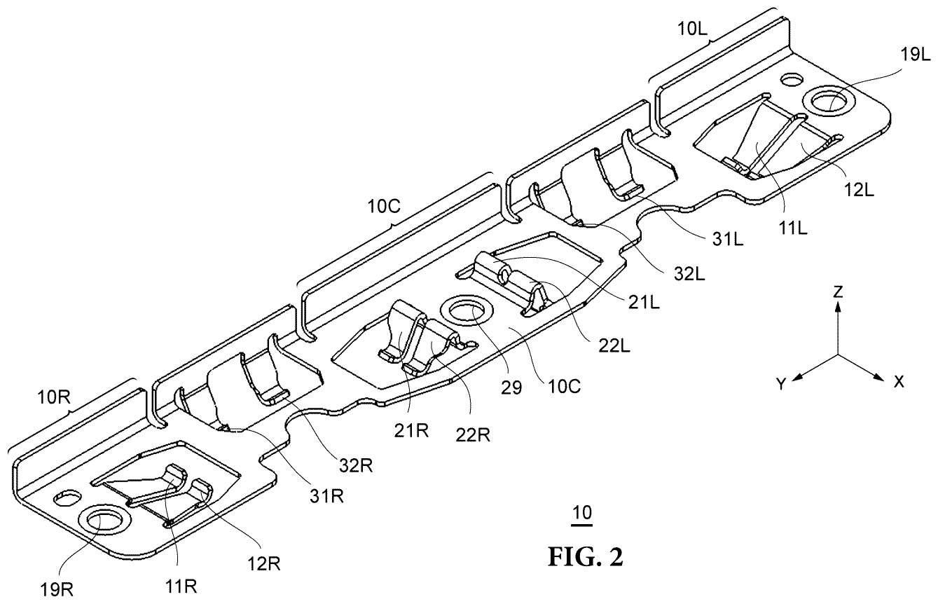

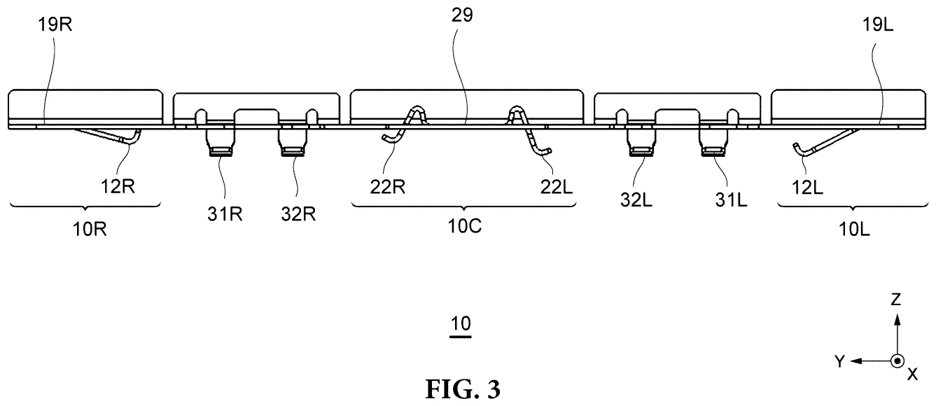

FIG. 2 is a perspective view showing an example of the pressing member 10 according to one aspect of the present disclosure, and FIG. 3 is a side view of the pressing member 10 shown in FIG. 2. As illustrated, the pressing member 10 is formed as a plate made of a metal material such as spring steel, and extends from a first end portion 10L to a second end portion 10R opposite to the first end portion 10L.

As in the illustrated example, a longitudinal direction Y of the pressing member 10 passing through the first and second end portions 10L, 10R may be parallel to a width direction of the housing 2. A width direction X of the pressing member 10 intersecting the longitudinal direction Y may be parallel to the longitudinal direction of the housing 2. A thickness direction Z of the pressing member 10 may be parallel to a height direction of the housing 2. The first end portion 10L is an example of one end portion including one end and a section in the vicinity thereof. The second end portion 10R is an example of the other end portion including the other end and a section in the vicinity thereof. The illustrated example may be reversed to the longitudinal direction Y so that the first end portion 10L becomes the other end portion and the second end portion 10R becomes the one end portion.

The pressing member 10 can be fixed to the substrate 3 or the housing 2 by fastening screws 9 or the like in a plurality of fixing portions 19L, 19R, 29. In the example shown in FIG. 1, the first fixing portion 19L provided on the first end portion 10L and the third fixing portion 19R provided on the second end portion 10R are fixed to the housing 2, and the second fixing portion 29 provided on an intermediate portion 10C between the first and second end portions 10L, 10R is fixed to the substrate 3.

The pressing member 10 includes a pair of first spring portions 11L, 12L and a pair of second spring portions 21L, 22L. In the illustrated example, the pressing member 10 further includes a pair of third spring portions 31L, 32L, a pair of fourth spring portions 11R, 12R, a pair of fifth spring portions 21R, 22R, and a pair of sixth spring portions 31R, 32R. The third to sixth spring portions 31L, 32L, 11R, 12R, 21R, 22R, 31R, 32R are not essential configurations, and therefore may be omitted. Each of the spring portions is capable of pressing an electronic component such as a semiconductor element toward the substrate 3.

The pair of first spring portions 11L, 12L are provided on the first end portion 10L, are arranged in the width direction X, and extend from the first fixing portion 19L toward the second fixing portion 29. More specifically, the first spring portion 11L has a base end fixed at a position adjacent to the first fixing portion 19L and a tip end moving freely due to elastic deformation. In the thickness direction of the pressing member 10, the tip end is located closer to the substrate 3 than the base end is. The same applies to the other first spring portion 12L.

The pair of second spring portions 21L, 22L are provided on the intermediate portion 10C, are arranged in the width direction X, and extend from the second fixing portion 29 toward the first fixing portion 19L. More specifically, the second spring portions 21L, 22L extend in the direction opposite to that of the first spring portions 11L, 12L, and the first spring portions 11L, 12L and the second spring portions 21L, 22L face each other. A base end of the second spring portion 21L is fixed at a position adjacent to the second fixing portion 29. The same applies to the other second spring portion 21R.

The pair of third spring portions 31L, 32L are provided between the first fixing portion 19L and the second fixing portion 29, are arranged in the longitudinal direction Y, and extend in the width direction X. That is, the third spring portions 31L, 32L extend in a direction not parallel to the first and second spring portions 11L, 12L, 21L, 22L. Similarly to the tip ends of the first spring portions 11L, 12L, the freely moving tip ends of the second and third spring portions 21L, 22L, 31L, 32L are positioned closer to the substrate 3 than the base ends are.

In the illustrated example, the pressing member 10 is formed in mirror symmetry with respect to a plane passing through the center of the second fixing portion 29. In other words, the pair of fourth spring portions 11R, 12R have substantially the same shape and function as the pair of first spring portions 11L, 12L. The pair of fifth spring portions 21R, 22R have substantially the same shape and function as the pair of second spring portions 21L, 22L. The pair of sixth spring portions 31R, 32R have substantially the same shape and function as the pair of first spring portions 31L, 32L. Therefore, the First to third spring portions 11L, 12L, 21L, 22L, 31L, 32L will be described in detail, while the redundant description for the fourth to sixth spring portions 11R, 12R, 21R, 22R, 31R, 32R will be omitted.

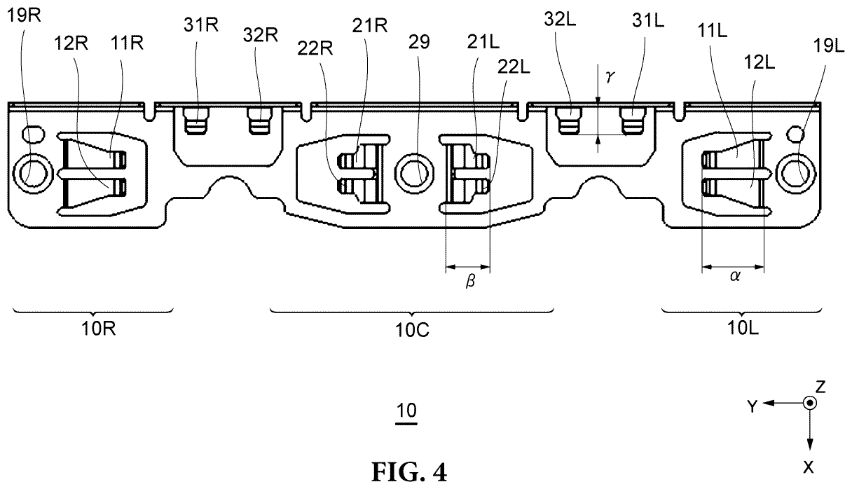

FIG. 4 is a plan view of the pressing member 10 shown in FIG. 2. In the longitudinal direction Y, the length of the first spring portion 11L, 12L is assumed to be α, and the length of the second spring portions 21L, 22L is assumed to be β. In the width direction X, the length of the third spring portions 31L, 32L is assumed to be γ. As shown in the diagram, the lengths α, β, γ may be different from each other. It is possible to change the lengths α, β, and γ of the first to third spring portions 11L, 12L, 21L, 22L, 31L, 32L so that electronic components can be pressed with an optimum pressing force.

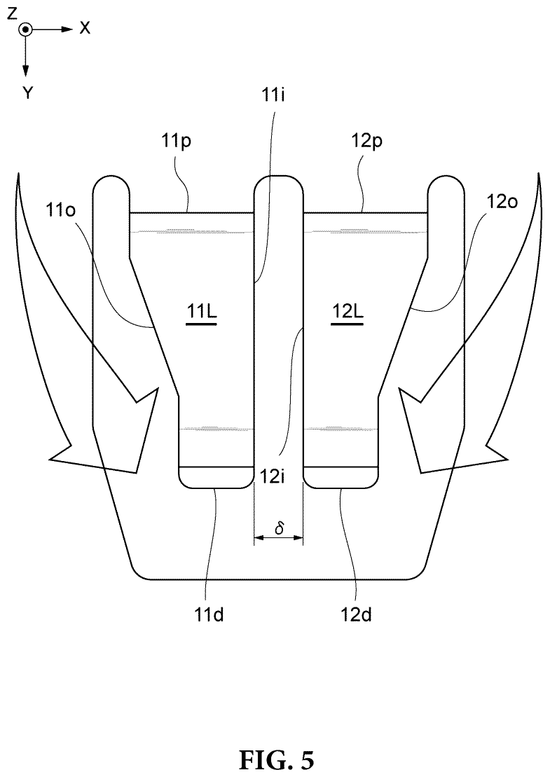

FIG. 5 is a plan view schematically showing the pair of first spring portions 11L, 12L shown in FIG. 4. As shown in FIG. 5, the pair of first spring portions 11L, 12L are arranged in the width direction X with a predetermined gap δ therebetween. The first spring portion 11L has an inner edge 11i proximal to the other first spring portion 12L and parallel to the longitudinal direction Y, and an outer edge 11o distant from the other first spring portion 12L and inclined toward the other first spring portion 12L from a base end 11p toward a tip end 11d.

The other first spring portion 12L also has similar inner edge 12i and outer edge 12o. The distance between the outer edges 11o, 12o of the pair of first spring portions 11L, 12L decreases from the base ends 11p, 12p toward the tip ends 11d 12d. In other words, the pair of first spring portions 11L, 12L are formed as a whole to become tapered toward the tip ends 11d, 12d from the base ends 11p, 12p.

Since the pair of first spring portions 11L, 12L are tapered, when one electronic component is pressed by using the two first spring portions 11L, 12L, the first spring portion 11L, 12L are less likely to protrude from the upper surface of the electronic component even if the electronic component is small in size. Since the gap δ is provided between the first spring portion 11L and the other first spring portion 12L, when each of the first spring portions 11L, 12L presses the electronic components one by one, the pair of first spring portions 11L, 12L can be arranged so as to extend over two electronic components.

Similarly to the pair of first spring portions 11L, 12L, the pair of second to sixth spring portions 21L, 22L, 31L, 32L, 11R, 12R, 21R, 22R, 31R, 32R are formed as a whole to be tapered in which the outer edges are inclined, and the pair of inner edges are arranged with a gap therebetween. Therefore, two spring portions can press one electronic component, or press extend over two electronic components.

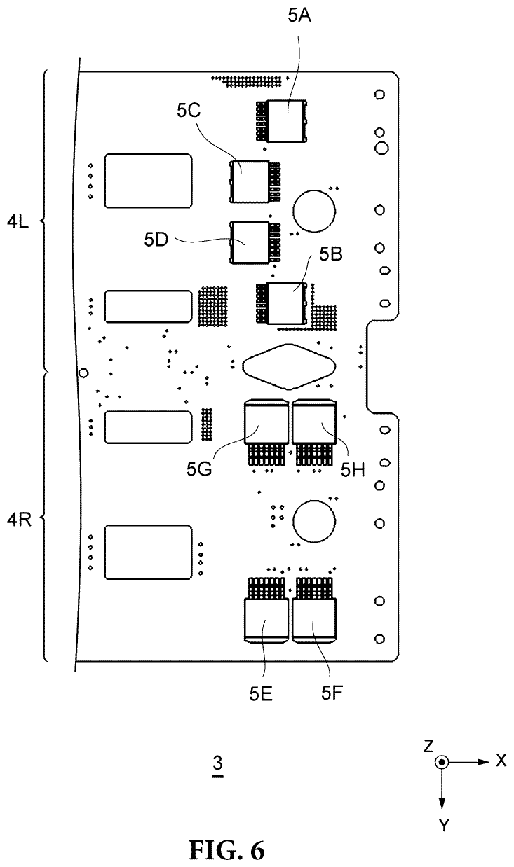

FIG. 6 is a plan view showing an example of the substrate 3 shown in FIG. 1. The power supply device 1 may be a DC/DC converter, an AC/DC converter, or a DC/AC inverter. When the power supply device 1 functions as a DC/DC converter, a high DC input voltage supplied from a high-voltage battery or the like storing a voltage of approximately 100 V to 800 V may be converted into a low DC output voltage, a voltage of approximately 12 V, for example, may be output as a first voltage from a first voltage output circuit 4L, and a voltage of approximately 48 V, for example, may be output as a second voltage from a second voltage output circuit 4R.

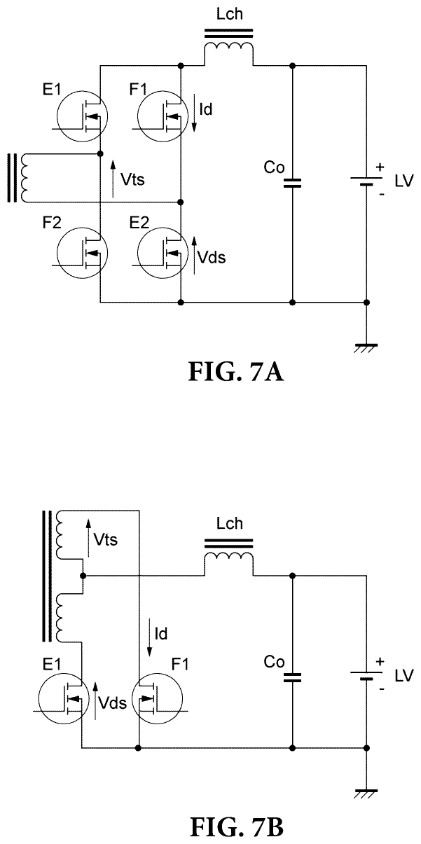

In the illustrated example, the substrate 3 includes the full-bridge type first voltage output circuit 4L and the center-tap type second voltage output circuit 4R. FIG. 7A is a circuit diagram for explaining the full-bridge type first voltage output circuit 4L shown in FIG. 6. FIG. 7B is a circuit diagram for explaining the center-tap type second voltage output circuit 4R shown in FIG. 6.

Contrary to the example shown in FIG. 6, the first voltage output circuit 4L may be of the center-tap type and the second voltage output circuit 4R may be of the full-bridge type. Both of the first and second voltage output circuits 4L, 4R may be of the full-bridge type. Both of the first and second voltage output circuits 4L, 4R may be of the center-tap type.

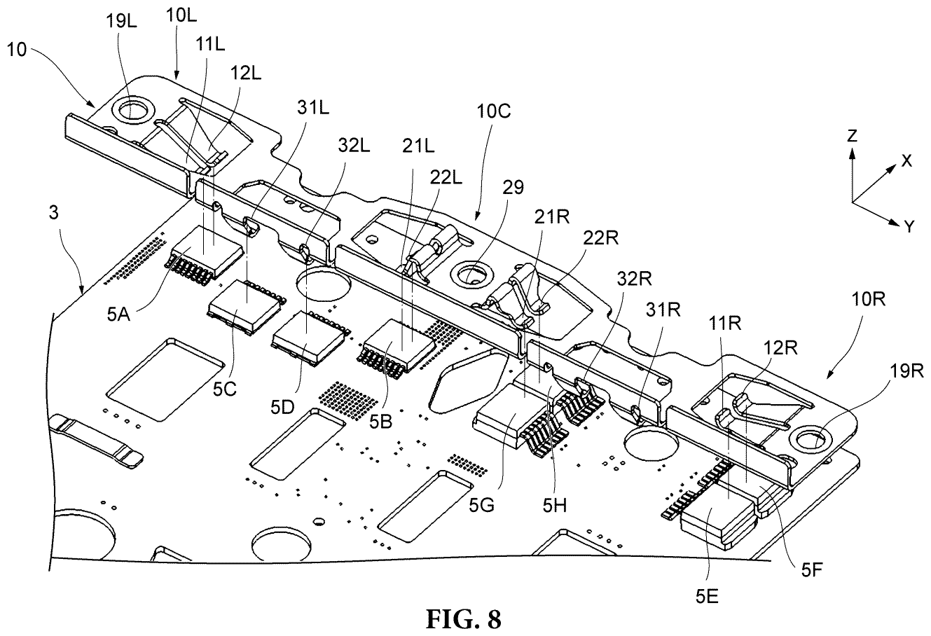

FIG. 8 is a perspective view showing an exploded view of the power supply device 1 in which the pressing member shown in FIG. 2 is attached to the substrate shown in FIG. 6. In the example shown in the diagram, in the first voltage output circuit 4L, the two first spring portions 11L, 12L press one electronic component 5A. The two second spring portions 21L, 22L press one electronic component 5B. The pair of third spring portions 31L, 32L are arranged to extend between two electronic components 5C, 5D, and the third spring portion 31L presses the electronic component 5C, while the other third spring portion 32L presses the electronic component 5D.

In the second voltage output circuit 4R, the pair of fourth spring portions 11R, 12R are arranged to extend between two electronic components 5E, 5F, and the fourth spring portion 11R presses the electronic component 5E, while the other fourth spring portion 12R presses the electronic component 5F. The pair of fifth spring portions 21R, 22R are arranged to extend between two electronic components 5G, 5H, and the fifth spring portion 21R presses the electronic component 5G, while the other fifth spring portion 22R presses the electronic component 5H.

As described above, the pressing member 10 is formed in mirror symmetry with respect to the plane passing through the center of the second fixing portion 29. Therefore, similarly to the fixation using the fourth spring portions 11R, 12R, the first spring portions 11L, 12L can be used for fixing. Similarly to the fixation using the fifth spring portions 21R, 22R, the second spring portions 21L, 22L can be used for fixing.

According to the pressing member 10 configured as described above, since the pair of first spring portions 11L, 12L arranged in the width direction X are provided, for example, the two first spring portions 11L, 12L can press a single electronic component (e.g., the electronic component 5A), and, for example, the first spring portion 11L can press an electronic component (e.g., the electronic component 5E), while the other first spring portion 12L presses another electronic component (e.g., the electronic component 5F). The same applies to the pairs of second to sixth spring portions 21L, 22L, 31L, 32L, 11R, 12R, 21R, 22R, 31R, 32R. Therefore, even if the design of the substrate 3 is changed, the pressing member 10 having the same shape can be used.

Because the first spring portions 11L, 12L and the second spring portions 21L, 22L are arranged so as to oppose each other in the longitudinal direction Y, and the pair of first spring portions 11L, 12L are arranged in the width direction X in a section adjacent to the first fixing portion 19L, the distance between the first and second fixing portions 19L, 29 is shorter as compared with the aspect described in Patent Publication JP-A-2016-63200 in which many spring portions are arranged in the longitudinal direction, and therefore the stress and reaction force of the first and second spring portions 11L, 12L, 21L, 22L can be adjusted easily. Accordingly, the electronic components can be pressed with an optimum pressing force. The same applies to the third to sixth spring portions 31L, 32L, 11R, 12R, 21R, 22R, 31R, 32R.

The example embodiments described above are for ease of understanding of the present disclosure and are not for limiting the present disclosure. The respective elements included in the example embodiments and the arrangements thereof, materials, conditions, shapes, sizes and the like are not limited to the illustrated examples, and can be changed as appropriate. It is also possible to partially substitute or combine the configurations shown in the different example embodiments.

1. A pressing member which is formed as a plate extending along a longitudinal direction from one end portion to the other end portion opposite to the one end portion, the pressing member comprising:
a first fixing portion provided on the one end portion and fixable to a substrate or a housing accommodating the substrate;
a second fixing portion provided on an intermediate portion between the one end portion and the other end portion and fixable to the substrate or the housing;
a pair of first spring portions that are provided on the one end portion, arranged in a width direction intersecting the longitudinal direction, extend from the first fixing portion toward the second fixing portion, and are elastically deformable; and
a pair of second spring portions that are provided on the intermediate portion, arranged in the width direction, extend from the second fixing portion toward the first fixing portion, and are elastically deformable.

2. The pressing member according to claim 1, further comprising a pair of third spring portions that are provided between the first fixing portion and the second fixing portion, are arranged in the lengthwise direction, extend in the width direction, and are elastically deformable.

3. The pressing member according to claim 1, wherein the pair of first spring portions and the pair of second spring portions are different in length in the longitudinal direction.

4. The pressing member according to claim 2, wherein the pair of first spring portions and the pair of second spring portions are different in length in the longitudinal direction.

5. The pressing member according to claim 2, wherein the length of the pair of first spring portions in the longitudinal direction is different from the length of the pair of third spring portions in the width direction.

6. The pressing member according to claim 4, wherein the length of the pair of first spring portions in the longitudinal direction is different from the length of the pair of third spring portions in the width direction.

7. The pressing member according to claim 1, wherein the first and second fixing portions are fixed to the substrate or the housing by means of fastening screws.

8. The pressing member according to claim 2, wherein the first and second fixing portions are fixed to the substrate or the housing by means of fastening screws.

9. The pressing member according to claim 3, wherein the first and second fixing portions are fixed to the substrate or the housing by means of fastening screws.

10. The pressing member according to claim 4, wherein the first and second fixing portions are fixed to the substrate or the housing by means of fastening screws.

11. The pressing member according to claim 5, wherein the first and second fixing portions are fixed to the substrate or the housing by means of fastening screws.

12. The pressing member according to claim 6, wherein the first and second fixing portions are fixed to the substrate or the housing by means of fastening screws.

13. A power supply device, comprising:
the pressing member according to claim 1; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.

14. A power supply device, comprising:
the pressing member according to claim 2; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.

15. A power supply device, comprising:
the pressing member according to claim 3; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.

16. A power supply device, comprising:
the pressing member according to claim 4; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.

17. A power supply device, comprising:
the pressing member according to claim 5; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.

18. A power supply device, comprising:
the pressing member according to claim 6; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.

19. A power supply device, comprising:
the pressing member according to claim 7; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.

20. A power supply device, comprising:
the pressing member according to claim 8; and
the substrate,
wherein the substrate includes a first voltage output circuit for outputting a first voltage, and a second voltage output circuit for outputting a second voltage, and
a semiconductor element mounted on the substrate constitutes the first and second voltage output circuits.
